(19) United States
(12) Patent Application Publication
(10) Pub. No.: US 2023/0085483 A1
(43) Pub. Date: Mar. 16, 2023

(54) BACKLIGHT MODULE, DISPLAY DEVICE INCLUDING THE SAME, AND METHOD FOR MAKING THE DISPLAY DEVICE

(71) Applicant: LI YUNG FAR TECHNOLOGY CO., LTD., Taoyuan City (TW)

(72) Inventor: Shao-Wei HUNG, Taoyuan City (TW)

(21) Appl. No.: 17/587,038

(22) Filed: Jan. 28, 2022

(30) Foreign Application Priority Data
Sep. 14, 2021 (TW) 110134247

(51) Int. Cl. H01L 25/075; H01L 33/50; H01L 33/58; H01L 33/60

(52) U.S. Cl. CPC H01L 25/0753; H01L 33/502; H01L 33/58; H01L 33/60; H01L 2933/0091; H01L 2933/0041; H01L 2933/0058

(57) ABSTRACT

A backlight module includes a substrate, a light blocking unit, and a plurality of light-emitting chips. The light blocking unit is disposed on the substrate, and includes a carbon black, a scattering particle and a resin. The scattering particle is one of titanium dioxide, silicon dioxide, barium sulfate, and combinations thereof. The light blocking unit cooperates with the substrate to form a plurality of spaced-apart wells. The light-emitting chips are disposed in the wells, respectively, to permit optical units to be disposed thereon. A display device including the backlight module, and a method for making the display device are also provided herein.

### CROSS-REFERENCE TO RELATED APPLICATION

This application claims priority of Taiwanese Invention Patent Application No. 110134247, filed on Sep. 14, 2021.

### FIELD

The disclosure relates to a display device, and more particularly to a backlight module, a display device including the same, and a method for making the display device.

### BACKGROUND

A quantum dot display device usually includes quantum dot units (e.g., quantum dot films or quantum dot glasses), and a backlight module. The backlight module includes a substrate, a plurality of light-emitting units disposed on the substrate, and a light blocking wall disposed on the substrate and surrounding the light-emitting units. The light blocking wall cooperates with the substrate to form a plurality of wells for receiving the light-emitting units and the quantum dot units. The light blocking wall includes a black photoresist that is made from chromium (Cr). The light blocking wall can be a black matrix (BM) made by subjecting the black photoresist to a photolithography process. Because the black photoresist has a high light absorption, the light blocking wall made therefrom can avoid optical crosstalk of light emitted from light-emitting devices.

However, in the quantum dot display device, when each of the quantum dot units is excited by light emitted from the respective one of the light-emitting units and then emits a white light, such white light will transmit through an optical structure which includes a diffusion film, a liquid crystal layer and a color filter, resulting in an energy loss of the white light and a poor luminous intensity of the quantum dot display device. In order to solve the abovementioned shortcomings, the thickness of the light blocking wall can be increased to increase the depth of the wells. Nevertheless, because the black photoresist easily absorbs light during the photolithography process, the uniformity and depth of light exposure might be adversely affected, causing the light blocking wall to be easily deformed, which limits the amount of the quantum dot units being filled in the wells.

Therefore, there is a need to improve the quantum dot display device.

### SUMMARY

An object of the disclosure is to provide a backlight module, a display device including the same, and a method for making the display device, which can alleviate or overcome the aforesaid shortcomings of the prior art.

According to a first aspect of the disclosure, a backlight module, which is adapted for use in a display device including a plurality of optical units, includes a substrate, a light blocking unit, and a plurality of light-emitting chips.

The light blocking unit is disposed on the substrate in a first direction, and has a thickness in the first direction ranging from 5 μm to 300 μm. The light blocking unit includes a carbon black, a scattering particle, and a resin. The scattering particle is selected from the group consisting of titanium dioxide, silicon dioxide, barium sulfate, and combinations thereof. The light blocking unit cooperates with the substrate to form a plurality of spaced-apart wells for receiving the optical units.

The wells are arranged in an array. The light blocking unit has a plurality of inner walls which define the wells with the substrate, and each of which forms an included angle with the substrate. The included angle ranges from 95 degrees to 150 degrees.

The light-emitting chips are disposed in the wells, respectively, to permit the optical units to be disposed thereon.

According to a second aspect of the disclosure, a display device includes the aforesaid backlight module, and a plurality of optical units disposed in the wells and on the light-emitting chips, respectively.

According to a third aspect of the disclosure, a method for making a display device includes the steps of:

a) preparing a mixture that includes a carbon black, a scattering particle, a resin, and a solvent;

b) forming a plurality of light-emitting chips on a chip region of a substrate, the light-emitting chips being spaced apart from each other;

c) forming a light blocking unit on the substrate, the light blocking unit being formed with a plurality of trenches located at the chip region of the substrate so that the light-emitting chips are exposed from the light blocking unit, the light blocking unit having a thickness measured from the substrate which ranges from 5 μm to 300 μm;

d) providing an optical material selected from the group consisting of red quantum dots, green quantum dots, blue quantum dots, light diffusion agent, and combinations thereof; and

e) applying the optical material in the trenches to form optical units on the light-emitting chips and in the trenches, respectively.

### BRIEF DESCRIPTION OF THE DRAWINGS

Other features and advantages of the disclosure will become apparent in the following detailed description of the embodiments with reference to the accompanying drawings, of which:

FIG. 1 is a fragmentary schematic view illustrating a first embodiment of a display device according to the disclosure;

FIG. 2 is a fragmentary schematic view illustrating a second embodiment of the display device according to the disclosure;

FIG. 3 is a fragmentary schematic view illustrating a variation of the second embodiment;

FIG. 4 is a fragmentary schematic view illustrating a third embodiment of the display device according to the disclosure;

FIG. 5 is a fragmentary schematic view illustrating a variation of the third embodiment;

FIG. 6 is a fragmentary schematic view illustrating a fourth embodiment of the display device according to the disclosure; and

FIG. 7 is a fragmentary schematic view illustrating a variation of the fourth embodiment.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted that, directional terms, such as “upper,” “lower,” “inner,” “top,” “up,” “down,” “left,” “right,” “front,” and “rear” may be used to assist in describing the disclosure based on the orientation of the embodiments shown in the figures. The use of these directional definitions should not be interpreted to limit the disclosure in any way. Furthermore, in this disclosure, an up-to-down or down-to-up direction may be referred to as an up-down direction, a right-to-left or left-to-right direction may be referred to as a left-right direction, and the front-to-rear or rear-to-front direction may be referred to as a front-rear direction. The device may be oriented at any angle, and the spatially relative descriptors used herein may be interpreted accordingly.

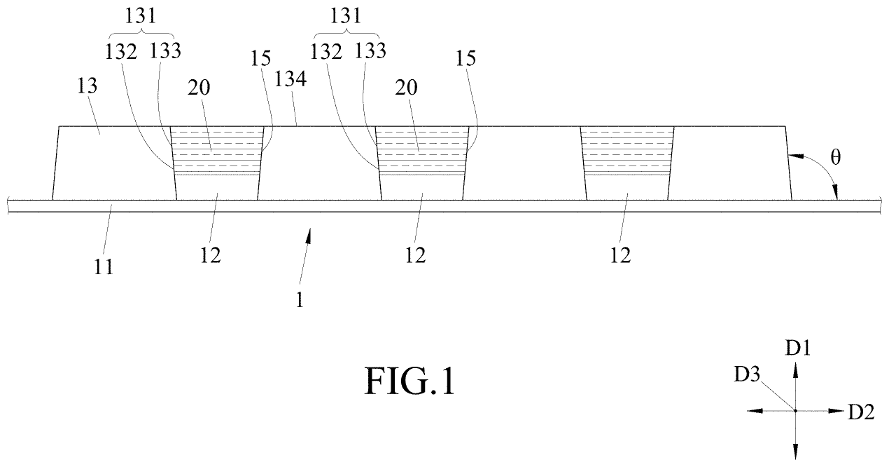

Referring to FIG. 1, a first embodiment of a display device according to the present disclosure includes a backlight module 1 and a plurality of optical units 20.

The backlight module 1 includes a substrate 11, a light blocking unit 13, and a plurality of light-emitting chips 12.

The light blocking unit 13 is disposed on the substrate 11 in a first direction (D1), and has a thickness in the first direction (D1) ranging from 5 μm to 300 μm, such as 10 μm to 200 μm. In this embodiment, the first direction (D1) is an up-down direction.

The light blocking unit 13 is made from a mixture that contains a carbon black, a scattering particle, and a resin, by curing. Examples of the scattering particle includes titanium dioxide (TiO₂), silicon dioxide (SiO₂), barium sulfate (BaSO₄), and any combinations thereof. The scattering particle is light-transmissive or white. The mixture may have a solid content that is greater than 95%.

The light blocking unit 13 cooperates with the substrate 11 to form a plurality of spaced-apart wells 15 for receiving the optical units 20. In certain embodiments, the wells 15 are arranged in an array, i.e., arranged in a second direction (D2) and a third direction (D3). In this embodiment, the second direction (D2) is the left-right direction, and the third direction (D3) is the front-rear direction. The light blocking unit 13 has a plurality of inner walls 131 which define the wells 15 with the substrate 11, and each of which forms an included angle (θ) with the substrate 11. The included angle (θ) ranges from 95 degrees to 150 degrees. In other words, each of the wells 15 has an inverted trapezoid cross-section in the first direction (D1). Each of the inner walls 131 has a lower portion 132 that connects to the substrate 11, and an upper portion 133 that connects to the lower portion 132 opposite to the substrate 11. In addition, the light blocking unit 13 further has a top surface 134 which connects to the upper portions 133 of the inner walls 131.

The light-emitting chips 12 are disposed in the wells 15, respectively. In some embodiments, each of the light-emitting chips 12 is one of a mini light-emitting diode (mini LED) and a micro light-emitting diode (micro LED).

The optical units 20 are disposed in the wells 15 and on the light-emitting chips 12, respectively. In this embodiment, the optical units 20 include quantum dots, and may be quantum dot films.

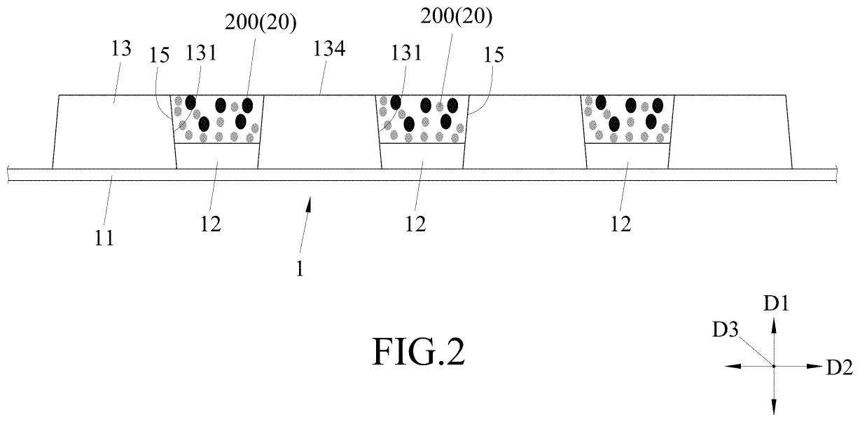

Referring to FIG. 2, a second embodiment of the display device according to the present disclosure is generally similar to the first embodiment, except for the following differences. Specifically, in the second embodiment, each of the optical units 20 includes an optical material 200 containing red quantum dots, green quantum dots, blue quantum dots and a light diffusion agent. Each of the optical units 20 receives light emitted from a respective one of the light-emitting chips 12 disposed thereunder to generate a white light. In addition, the light blocking unit 13 is white, which may enhance the reflectivity of light emitted from the light-emitting chips 12 and transmitted to the inner walls 131, and which is conducive to excite the optical units 20 to emit light having a high luminous intensity.

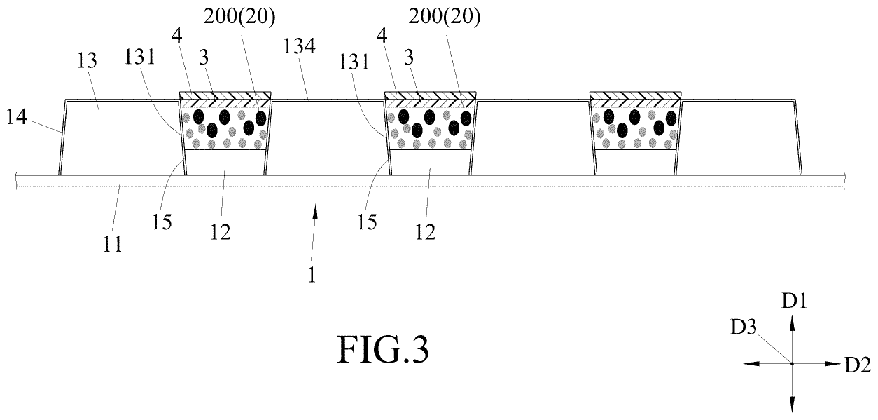

Referring to FIG. 3, in a variation of the second embodiment, the display device further includes a plurality of optical layers 3 and a plurality of packaging layers 4.

Each of the optical layers 3 is disposed on a respective one of the optical units 20, and seals a respective one of the wells 15. The optical layer 3 may include one of an organic dye, a material for adjusting refractive index, an optical polarizing material, a light diffusive material, and any combinations thereof.

Each of the packaging layers 4 is disposed on a respective one of the optical layers 3 opposite to the substrate 11, and may include one of an inorganic barrier material for blocking water and oxygen, an organic thin film material, and a combination thereof. The inorganic barrier material for blocking water and oxygen may be aluminum oxide (Al₂O₃), titanium dioxide (TiO₂), or silicon dioxide (SiO₂). The organic thin film material may be parylene, organic nitrosilicide, organic silicon oxide, or organic acrylic resin.

In addition, in this variation, the backlight module 1 further includes a reflection layer 14 that is disposed on the light blocking unit 13, and that has a reflectivity greater than 15%. The reflection layer 14 is capable of reflecting light emitted from the light-emitting chips 12, which is conducive to excite the optical units 20 to emit light having a high luminous intensity.

In another variation of the second embodiment, in order to adjust the reflectivity of light emitted from the light-emitting chips 12 and transmitted to the light blocking unit 13, the light blocking unit 13 may be gray.

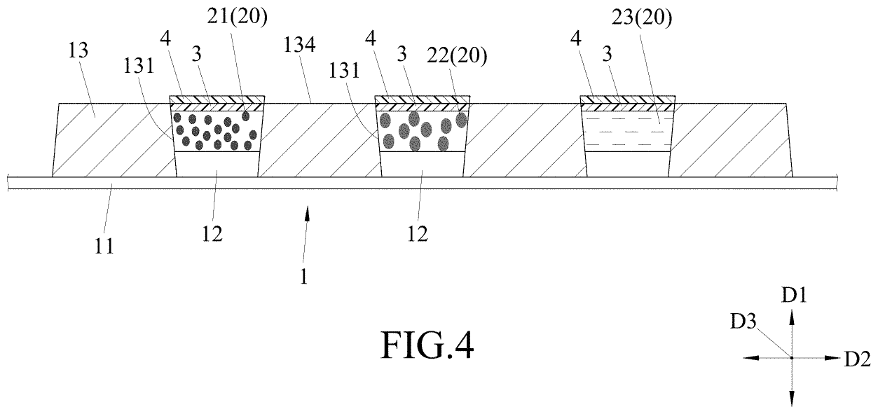

Referring to FIG. 4, a third embodiment of the display device according to the present disclosure is generally similar to the variation of the second embodiment, except for the following differences.

Specifically, the optical units 20 are divided into a plurality of groups each containing a first optical unit 21, a second optical unit 22 and a third optical unit 23 in the given order along the second direction (D2) that is perpendicular to the first direction (D1). For each of the groups, the first optical unit 21 includes a red quantum dot material for emitting a red light, the second optical unit 22 includes a green quantum dot material for emitting a green light, and the third optical unit 23 includes one of a blue quantum dot material, a light diffusion agent and a combination thereof, for emitting a blue light. In addition, the light blocking unit 13 is black, so that light emitted from the light-emitting chips 12 may be easily absorbed by the light blocking unit 13, and the optical crosstalk may be reduced.

It is noted that the material of the third optical unit 23 can be adjusted according to light emitted from the respective one of the light-emitting chips 12. For example, the third optical unit 23 may only include the light diffusion agent when the respective one of the light-emitting chips 12 emits the blue light.

It is noted that the reflection layer 14 may be omitted in this embodiment.

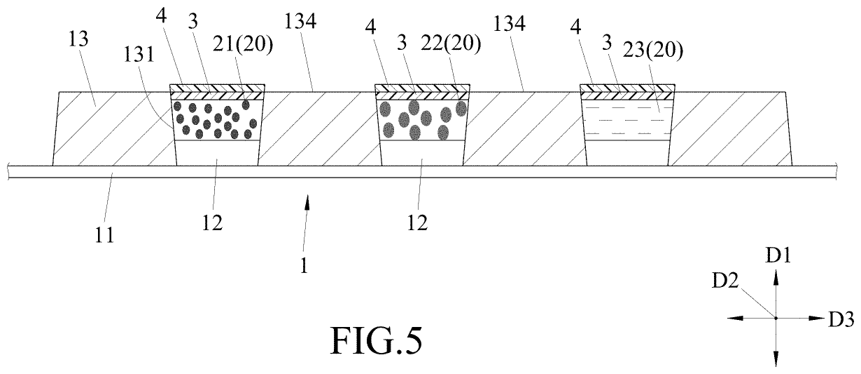

Referring to FIG. 5, in a variation of the third embodiment, the first optical unit 21, the second optical unit 22 and the third optical unit 23 in each group of the optical units 20 are arranged in the given order along the third direction (D3) that is perpendicular to the first direction (D1) and the second direction (D2).

In another variation of the third embodiment, in order to adjust the reflectivity of light emitted from the light-emitting chips 12 and transmitted to the light blocking unit 13, the light blocking unit 13 may be gray.

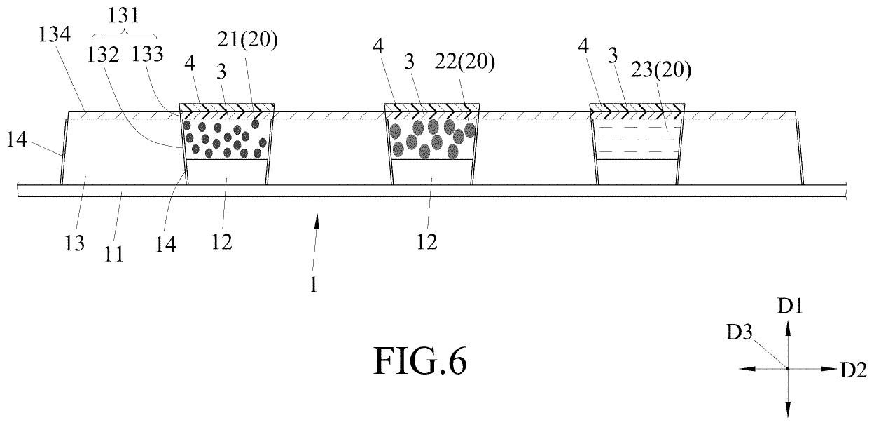

Referring to FIG. 6, a fourth embodiment of the display device according to the present disclosure is generally similar to the third embodiment, except for the following differences.

Specifically, the lower portion 132 of each of the inner walls 131 is white, the upper portion 133 of each of the inner walls 131 is black, and the top surface 134 is black. In addition, the backlight module 1 further includes a reflection layer 14 disposed on the lower portions 132 of the inner walls 131. The reflection layer 14 may have a reflectivity greater than 15%.

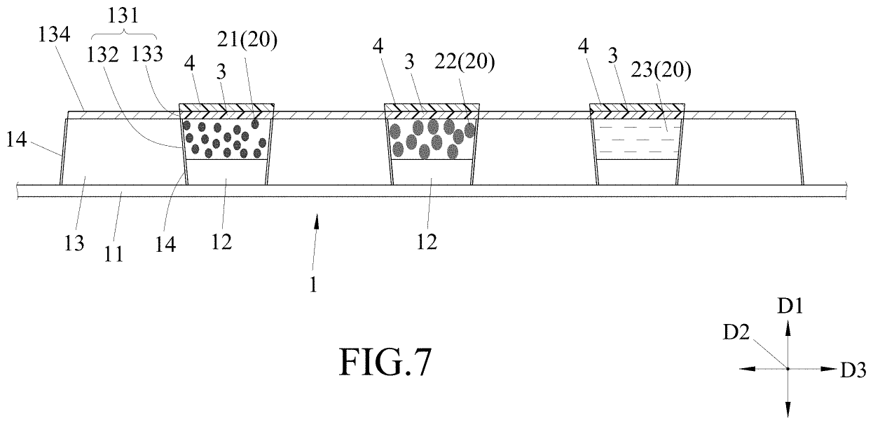

Referring to FIG. 7, in a variation of the fourth embodiment, the first optical unit 21, the second optical unit 22 and the third optical unit 23 in each group of the optical units 20 are arranged in the given order along the third direction (D3).

With the lower portion 132 being white, the reflectivity of the lower portion 132 may be increased. Moreover, with the upper portions 133 and the top surface 134 being black, light emitted from the first optical unit 21, the second optical unit 22, and the third optical unit 23 in each group of the optical units 20 may be easily absorbed by the upper portions 133 and the top surface 134, thereby reducing the optical crosstalk.

This disclosure also provides a method for making the first embodiment of the display device, which includes the following consecutive steps S11 to S15.

In step S11, a mixture that includes a carbon black, a scattering particle, a resin, and a solvent is prepared.

In step S12, the light-emitting chips 12 are formed on a chip region of the substrate 11, and are spaced apart from each other.

In step S13, the light blocking unit 13 is formed on the substrate 11. The light blocking unit 13 is formed with a plurality of trenches located at the chip region of the substrate 11 so that the light-emitting chips 12 are exposed from the light blocking unit 13. The light blocking unit 13 has a thickness measured from the substrate 11 which ranges from 5 μm to 300 μm. Step S13 may be performed by one of an inkjet printing process, a laser engraving process, and an imprinting process, which are described as follows, respectively.

### Inkjet Printing

The mixture is applied on the substrate 11 at a predetermined position using an inkjet printing device such as an inkjet printer or a three dimensional printer according to a printing program, followed by curing the mixture using ultraviolet radiation (e.g., an ultraviolet curing lamp), so as to form the light blocking unit 13.

### Laser Engraving

The mixture is applied on a plate, followed by curing the mixture using ultraviolet radiation (e.g., using an ultraviolet curing lamp), so as to form a mixture layer. Portions of the mixture layer in positional correspondence with the light-emitting chips 12 are removed using a laser engraver, so as to obtain the light blocking unit 13. The light blocking unit 13 is then transferred from the plate to the substrate 11. The plate may be removed from the light blocking unit 13 by a stripping technique after the light blocking unit 13 is bonded to the substrate 11.

### Imprinting

The mixture is applied on a plate, and is imprinted by a nanoimprinting process (e.g., using a nanoimprinter), so as to form an imprinting layer having a plurality of through holes in positional correspondence with the light-emitting chips 12. The imprinting layer is cured using ultraviolet radiation (e.g., using an ultraviolet curing lamp), so as to obtain the light blocking unit 13. The light blocking unit 13 is then transferred from the plate to the substrate 11. The plate may be removed from the light blocking unit 13 by a stripping technique after the light blocking unit 13 is bonded to the substrate 11. In step S14, an optical material 200 is provided. The optical material 200 may be one of red quantum dots, green quantum dots, blue quantum dots, light diffusion agent, and any combinations thereof.

In step S15, the optical material 200 is applied in the trenches to form the optical units 20 on the light-emitting chips 12, respectively. Step S15 may be performed by one of an inkjet printing process and a photolithography process, which are described as follows, respectively.

### Inkjet Printing

Step S15 may involve applying the optical material 200 on the light emitting chips 12 and in the trenches using an inkjet printing device, such as an inkjet printer.

### Photolithography

Step S15 may include (i) applying a photoresist layer that includes the optical material 200 on the light blocking unit (13) and in the trenches, followed by baking the photoresist layer, and (ii) exposing and developing the photoresist layer to remove a portion of the photoresist layer on the top surface 134 of the light blocking unit 13, so as to form the optical units 20 on the light-emitting chips 12 and in the trenches, respectively.

It is noted that additional steps can be added before, after or during the aforesaid steps of the method for making the first embodiment of the display device, and some of the steps described herein may be replaced by other steps or be eliminated.

In sum, by having the light blocking unit 13 that includes the carbon black, the scattering particle and the resin, that has an included angle (θ) ranging from 95 degrees to 150 degrees, and that has a thickness in the first direction (D1) ranging from 5 μm to 300 μm, the luminous efficiency and intensity of the display device can be enhanced.

In the description above, for the purposes of explanation, numerous specific details have been set forth in order to provide a thorough understanding of the embodiment. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. A backlight module, which is adapted for use in a display device including a plurality of optical units, comprising:
a substrate;
a light blocking unit disposed on said substrate in a first direction and having a thickness in the first direction ranging from 5 μm to 300 μm, said light blocking unit including a carbon black, a scattering particle, and a resin, said scattering particle being selected from the group consisting of titanium dioxide, silicon dioxide, barium sulfate, and combinations thereof, said light blocking unit cooperating with said substrate to form a plurality of spaced-apart wells for receiving the optical units, said wells being arranged in an array, said light blocking unit having a plurality of inner walls which define said wells with said substrate, and each of which forms an included angle with said substrate, said included angle ranging from 95 degrees to 150 degrees; and
a plurality of light-emitting chips disposed in said wells, respectively, to permit the optical units to be disposed thereon.

2. The backlight module of claim 1, wherein each of said light-emitting chips is one of a mini light-emitting diode (mini LED) and a micro light-emitting diode (micro LED).

3. The backlight module of claim 1, wherein said light blocking unit is white.

4. The backlight module of claim 1, wherein said light blocking unit is black.

5. The backlight module of claim 1, wherein said light blocking unit is gray.

6. The backlight module of claim 1, wherein each of said inner walls has a lower portion that connects to said substrate and that is white, and an upper portion that connects to said lower portion opposite to said substrate and that is black.

7. The backlight module of claim 1, further comprising a reflection layer that is disposed on said light blocking unit, and that has a reflectivity greater than 15%.

8. A display device, comprising a backlight module as claimed in claim 1, and a plurality of optical units disposed in said wells and on said light-emitting chips, respectively.

9. The display device of claim 8, further comprising a plurality of optical layers and a plurality of packaging layers, each of said optical layers disposed on a respective one of said optical units and sealing a respective one of said wells, each of said packaging layers being disposed on a respective one of said optical layers, and including one of an inorganic barrier material for blocking water and oxygen, an organic thin film material and a combination thereof.

10. The display device of claim 8, wherein each of said optical units includes an optical material containing red quantum dots, green quantum dots, blue quantum dots and a light diffusion agent for receiving a light emitted from a respective one of said light-emitting chips to generate a white light, the light blocking unit being white.

11. The display device of claim 8, wherein
said optical units are divided into a plurality of groups each containing a first optical unit, a second optical unit and a third optical unit in the given order along a second direction that is perpendicular to the first direction, and
for each of the groups, said first optical unit includes a red quantum dot material for emitting a red light, said second optical unit including a green quantum dot material for emitting a green light, said third optical unit including one of a blue quantum dot material, a light diffusion agent and a combination thereof, for emitting a blue light and
said light blocking unit is gray.

12. The display device of claim 8, wherein
said optical units are divided into a plurality of groups each containing a first optical unit, a second optical unit and a third optical unit in the given order along a third direction that is perpendicular to the first direction, and
for each of the groups, said first optical unit includes a red quantum dot material for emitting a red light, said second optical unit including a green quantum dot material for emitting a green light, said third optical unit including one of a blue quantum dot material, a light diffusion agent and a combination thereof for emitting a blue light, and
said light blocking unit is black.

13. The display device of claim 8, wherein
said optical units are divided into a plurality of groups each containing a first optical unit, a second optical unit and a third optical unit in the given order along a second direction that is perpendicular to the first direction, and
for each of the groups, said first optical unit includes a red quantum dot material for emitting a red light, said second optical unit including a green quantum dot material for emitting a green light, said third optical unit including one of a blue quantum dot material, a light diffusion agent and a combination thereof for emitting a blue light, and
each of said inner walls has a lower portion that connects to said substrate and that is white, and an upper portion that connects to said lower portion opposite to said substrate and that is black.

14. The display device of claim 8, wherein
said optical units are divided into a plurality of groups each containing a first optical unit, a second optical unit and a third optical unit in the given order along a third direction that is perpendicular to the first direction, and
for each of the groups, said first optical unit includes a red quantum dot material for emitting a red light, said second optical unit including a green quantum dot material for emitting a green light, said third optical unit including one of a blue quantum dot material, a light diffusion agent and a combination thereof for emitting a blue light, and
each of said inner walls has a lower portion that connects to said substrate and that is white, and an upper portion that connects to said lower portion opposite to said substrate and that is black.

15. A method for making a display device, comprising the steps of:
a) preparing a mixture that includes a carbon black, a scattering particle, a resin, and a solvent;
b) forming a plurality of light-emitting chips on a chip region of a substrate, the light-emitting chips being spaced apart from each other;
c) forming a light blocking unit on the substrate, the light blocking unit being formed with a plurality of trenches located at the chip region of the substrate so that the light-emitting chips are exposed from the light blocking unit, the light blocking unit having a thickness measured from the substrate which ranges from 5 μm to 300 μm;
d) providing an optical material selected from the group consisting of red quantum dots, green quantum dots, blue quantum dots, light diffusion agent, and combinations thereof; and
e) applying the optical material in the trenches to form optical units on the light-emitting chips and in the trenches, respectively.

16. The method of claim 15, wherein step c) includes the sub-steps of:
c1) applying the mixture on the substrate by an inkjet printing process; and
c2) curing the mixture using ultraviolet radiation, so as to form the light blocking unit.

17. The method of claim 15, wherein step c) includes the sub-steps of:
c1) applying the mixture on a plate, followed by curing the mixture using ultraviolet radiation, so as to form a light blocking layer;
c2) removing portions of the light blocking layer in positional correspondence with the light-emitting chips by a laser engraving process, so as to obtain the light blocking unit; and
c3) transferring the light blocking unit from the plate to the substrate.

18. The method of claim 15, wherein step c) includes the sub-steps of:
c1) applying the mixture on a plate;
c2) imprinting the mixture by a nanoimprinting process, so as to form an imprinting layer having a plurality of through holes in positional correspondence with the light-emitting chips;
c3) curing the imprinting layer using ultraviolet radiation, so as to obtain the light blocking unit; and
c4) transferring the light blocking unit from the plate to the substrate.

19. The method of claim 15, wherein in step e), the optical material is applied on the light emitting chips and in the trenches by an inkjet printing process.

20. The method of claim 15, wherein step e) includes the sub-steps of:
e1) applying a photoresist layer that includes the optical material on the light blocking unit and in the trenches, followed by baking the photoresist layer; and
e2) exposing and developing the photoresist layer to remove a portion of the photoresist layer on the light blocking unit, so as to form the optical units on the light-emitting chips and in the trenches, respectively.
